(19) United States
(12) Patent Application Publication
(10) Pub. No.: US 2016/0178279 A1
(43) Pub. Date: Jun. 23, 2016

(54) SUBSTRATE EDGE RESIDUE REMOVAL SYSTEMS, APPARATUS, AND METHODS

(71) Applicant: Applied Materials, Inc., Santa Clara, CA (US)

(72) Inventors: Edwin Velazquez, Union City, CA (US); Ekaterina Mikhaylichenko, San Jose, CA (US)

(21) Appl. No.: 14/602,114

(22) Filed: Jan. 21, 2015

Related U.S. Application Data
(60) Provisional application No. 62/094,938, filed on Dec. 19, 2014.

(51) Int. Cl. F26B 21/00; F26B 3/04; F26B 25/00; B08B 5/00

(52) U.S. Cl. CPC F26B 21/004; B08B 5/00; F26B 3/04; F26B 25/004

(57) ABSTRACT

In one or more embodiments, a substrate edge residue removal apparatus is provided. A substrate edge residue removal apparatus includes a lower body including a gas cavity; and an upper plate removably coupled to the lower body, wherein the lower body and upper plate together form an assembly having a passageway leading from the gas cavity to a plenum and an output slit extending along a length of the plenum and in fluid communication with the plenum. Assemblies including the substrate edge residue removal apparatus and methods of cleaning substrates with the substrate edge residue removal apparatus are provided, as are numerous additional aspects.

### RELATED APPLICATIONS

The present application claims priority from U.S. Application Ser. No. 62/094,938, filed Dec. 19, 2014, and titled “SUBSTRATE RINSING SYSTEMS AND METHODS” (Docket No. 22585), which is hereby incorporated by reference herein in its entirety for all purposes.

The present application is related to U.S. application Ser. No. 14/593,841, filed Jan. 9, 2015, and titled “SUBSTRATE HOLDER ASSEMBLY, APPARATUS, AND METHODS” (Docket No. 22564), which is hereby incorporated by reference herein in its entirety for all purposes.

The present application is related to U.S. Application Ser. No. ______, filed ______, and titled “SUBSTRATE GRIPPER APPARATUS AND METHODS” (Docket No. 22600), which is hereby incorporated by reference herein in its entirety for all purposes.

The present application is related to U.S. application Ser. No. ______, filed ______, and titled “SYSTEMS AND METHODS FOR RINSING AND DRYING SUBSTRATES” (Docket No. 22586), which is hereby incorporated by reference herein in its entirety for all purposes.

### FIELD

Embodiments of the invention relate generally to electronic device manufacturing including chemical mechanical planarization (CMP), and more particularly to substrate edge residue removal systems, apparatus and methods adapted to clean substrates after CMP.

### BACKGROUND

After a chemical mechanical planarization (CMP) process is performed on a substrate, the substrate is typically cleaned to remove unwanted debris and particles therefrom. For example, slurry, polished substrate material or other residue may cling to the substrate, including the edge bevel of the substrate. Following CMP, substrates may be post-cleaned in a cleaning module such as a scrubber brush box, a megasonic tank, or the like to remove such unwanted material. Prior to the post-clean, and even after the post-clean, a rinse in a rinse tank may be used in some embodiments.

During the rinsing operations, the substrates can be dried upon being removed from a rinsing tank. Such drying is typically accomplished by use of an air or vapor (e.g., IPA vapor) knife, such as a Marangoni knife which directs gas at an interface (e.g., the meniscus formed) between the substrate and rinse fluid as the substrate is lifted out of a bath of the rinse fluid. In Marangoni drying, a substrate is raised in a vertical orientation from a fluid bath, and an alcohol vapor is delivered to a meniscus that is formed at the substrate/fluid interface. The alcohol vapor reduces the surface tension at the meniscus, thereby creating a “Marangoni” force resulting in a downward liquid flow opposite to the substrate lift direction. As a result, the substrate surface above the meniscus is dried. However, some bath residue may be difficult to remove using such conventional drying methods. Thus, improved systems, apparatus, and methods of removing residue from a substrate are desired.

### SUMMARY

In some embodiments, a substrate edge residue removal system is provided. The substrate edge residue removal system includes an assembly formed from a lower body including a gas cavity and an upper plate removably coupled to the lower body wherein the assembly includes a passageway leading from the gas cavity to a plenum and an output slit extending along a length of the plenum and in fluid communication with the plenum; a frame supporting the assembly; a Marangoni drying device coupled to the frame and disposed below the assembly; and a substrate holder operable to support and to lift a substrate past the output slit of the assembly.

In some embodiments, a substrate edge residue removal apparatus adapted to clean a substrate is provided. The substrate edge residue removal apparatus includes a lower body including a gas cavity; and an upper plate removably coupled to the lower body. The lower body and upper plate together form an assembly having a passageway leading from the gas cavity to a plenum and an output slit extending along a length of the plenum and in fluid communication with the plenum.

In some embodiments, a method of removing residue from a substrate edge is provided. The method includes supporting a substrate on a substrate holder in a vertical orientation while lifting the substrate upward past a drying device; activating a substrate edge residue removal apparatus to apply a curtain of gas to a lower portion of the substrate once the substrate has been lifted past the drying device; and continuing to lift the substrate upward past the substrate edge residue removal apparatus such that the curtain of gas removes substantially all of the liquid from the substrate without leaving a residue.

Other features and aspects of embodiments of the invention will become more fully apparent from the following detailed description of example embodiments, the appended claims, and the accompanying drawings.

### BRIEF DESCRIPTION OF THE DRAWINGS

Various embodiments of the invention are disclosed in the following detailed description and accompanying drawings.

FIG. 1 illustrates a perspective view of an example substrate edge residue removal system in accordance with one or more embodiments of the present invention.

FIG. 2 illustrates a side view of an example substrate edge residue removal system in accordance with one or more embodiments of the present invention.

FIG. 3 illustrates a perspective view of an example substrate edge residue removal apparatus in accordance with one or more embodiments of the present invention.

FIG. 4 illustrates an exploded perspective view of an example of substrate edge residue removal apparatus in accordance with one or more embodiments of the present invention.

FIG. 5 illustrates a side cross-sectional view of an example of substrate edge residue removal apparatus in accordance with one or more embodiments of the present invention.

FIG. 6 illustrates a view of an example substrate holder for a substrate edge residue removal system in accordance with one or more embodiments of the present invention.

FIG. 7 is a flowchart depicting an example method of operating a substrate edge residue removal system in accordance with one or more embodiments of the present invention.

FIG. 8 illustrates a view of a second example substrate holder for a substrate edge residue removal system in accordance with one or more embodiments of the present invention.

### DESCRIPTION

In one or more embodiments of the present invention, a substrate edge residue removal apparatus is provided. The substrate edge residue removal apparatus especially aids in cleaning the lower edges of a substrate being held vertically, as well as around the substrate contact locations, and may therefore avoid residue buildup on a lower edge of the substrate, and/or around the substrate contact locations.

In some embodiments, following CMP, substrates may be rinsed in a post-CMP rinse, and then may be transferred directly to a post-cleaning module, such as a scrubber brush box, a megasonic tank, or the like, for further cleaning. However, during the rinsing and conventional drying process, as the substrate is retracted from the rinse bath, some adhered particles and/or residues may still remain, especially on contact points, and along a bottom edge of the substrate. Thus, embodiments of the present invention provide a substrate edge residue removal apparatus and operational methods that provide improved residue removal after a substrate has, for example, been removed from a rinsing bath and dried using conventional processes.

In some embodiments, a substrate edge residue removal apparatus is configured and adapted to eliminate or minimize liquid entrapment at the bottom of the substrate (and/or at finger contact points of a substrate holder) that may remain even after a conventional substrate drying process, such as a surface tension Marangoni process. Prior art systems typically rely on evaporation to remove liquid left behind on the substrate edge by the Marangoni or other processes. However, if such liquid residue is permitted to merely evaporate, a solid residue (e.g., a water mark) may remain, adhered to the substrate edge location where the liquid evaporated. This residue can result in contamination of the substrate and introduction of defects.

Instead of evaporatively drying liquid residue after a Marangoni or other process, embodiments of the present invention blow the liquid off (e.g., physically displace the liquid) via force from pressurized gas (e.g., nitrogen (N₂)) flowed from the substrate edge residue removal apparatus so that neither liquids nor solids remain. In some embodiments, the gas used can be an N₂ and isopropyl alcohol (IPA) vapor mix (e.g., with a relatively high moisture content) that insures the liquid residue is blown-off without first drying.

Some embodiments include a two piece assembly formed from a lower body removably coupled to an upper plate. Gas is flowed through the assembly and exits via a thin output slit formed by a gap between the two pieces of the assembly. In some embodiments, the gas is flowed at a rate sufficiently low enough to maintain an even laminar flow. In some embodiments, the slit's output direction is angled downward and the apparatus is only activated as the lower third of the substrate is passed by the output slit. After the substrate has passed the conventional drying process devices (e.g., a Marangoni dryer), the substrate edge residue removal apparatus is activated directing a vapor or gas curtain on the major surface of the substrate that blows any residue off of the substrate face and edge, as well as off of the fingers of the substrate holder as the substrate is lifted past the apparatus.

In some embodiments, the substrate holder may include vacuum slots adapted to draw in liquid that is blown off of the substrate by the substrate edge residue removal apparatus. Operation of the vacuum slots can be synchronized with operation of the substrate edge residue removal apparatus. In other words, at the same time the gas curtain is activated and applied to a passing substrate but the substrate edge residue removal apparatus, vacuum pressure can be applied to the substrate edge from the vacuum slots in the substrate holder.

As used herein unless otherwise specified, the term “clean” is intended to mean the removal of solids, liquids, residues, or other particles that are on, in contact with, or have become adhered to a substrate. These and other features and embodiments of the invention will be described in more detail below with reference to the drawings.

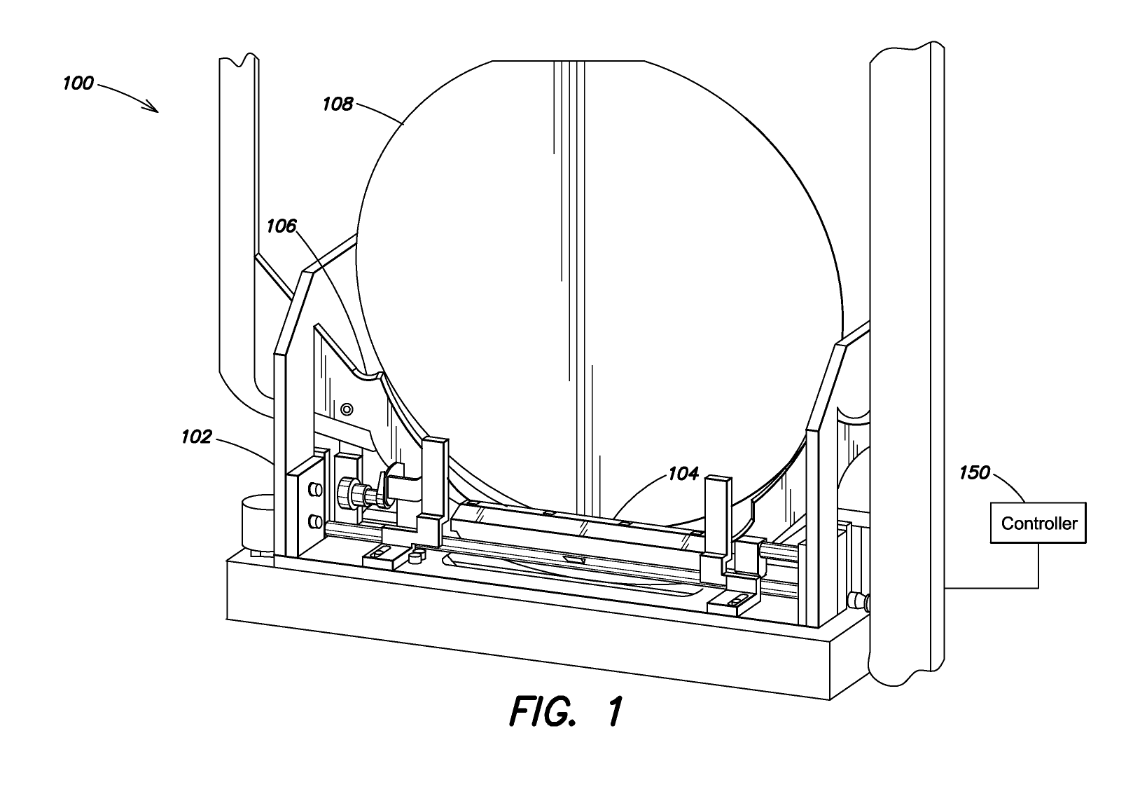

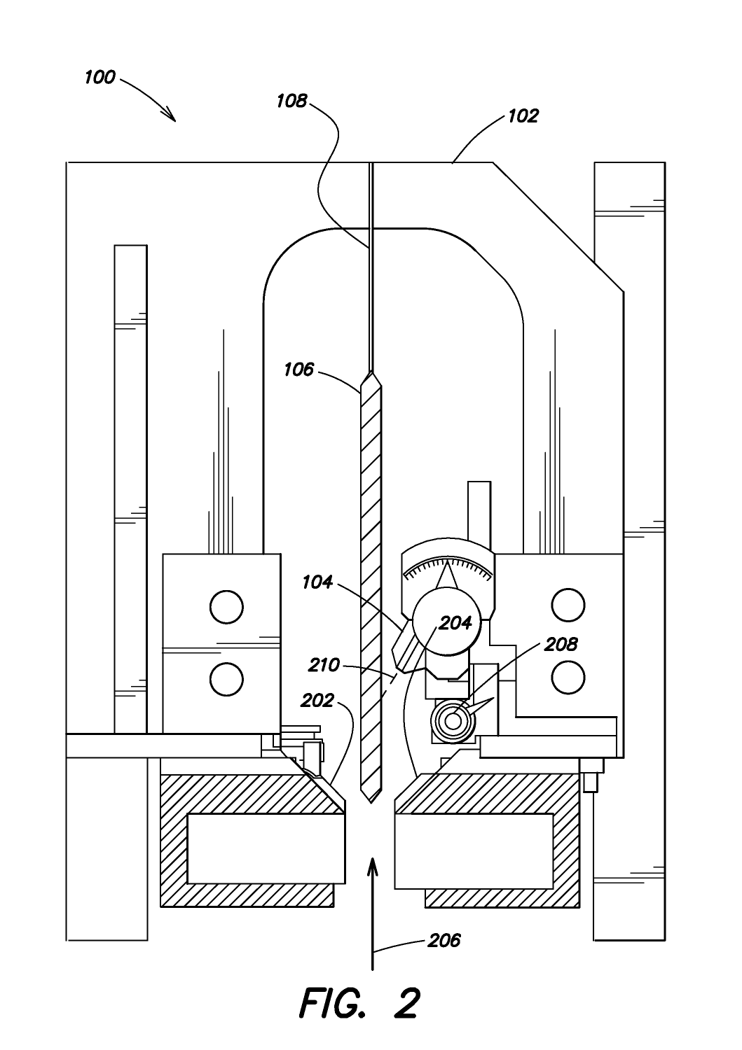

Turning now to FIG. 1, a perspective view of a substrate edge residue removal system 100 is depicted. The system 100 includes a frame 102 adapted to support a substrate edge residue removal apparatus 104. A substrate holder 106 is provided to support a substrate 108 to be cleaned and to lift the substrate 108 past the substrate edge residue removal apparatus 104. In some embodiments, the substrate edge residue removal system 100 can include a controller 150 coupled to one or more actuators (e.g., a gas supply valve actuator, a robot, a lift motor, etc.)(not shown) and operative to activate/de-activate the substrate edge residue removal apparatus 104 and to control movement of the substrate holder 106. FIG. 2 depicts a side view of the system 100 to better illustrate the relative positions of the system components as well as additional system components.

As can be seen in FIG. 2, the frame 102 also supports a pair of waterfall heads 202, 204 disposed on either side of the path of the substrate indicated by arrow 206. The waterfall heads 202, 204 are adapted to apply a rinse liquid (e.g., deionized (DI) water) to both sides of the substrate 108 concurrently. In the depicted example embodiment, located above the right hand waterfall head 204, a conventional Marangoni dryer device 208 is positioned to apply IPA vapor to the interface between rinse liquid from the waterfall head 204 and the substrate 108. Using surface tension created by application of the vapor by the Marangoni dryer device 208, the rinse liquid is pulled off of the substrate. Typically however, not all the rinse liquid is removed. Particularly along the lower substrate edge, residue remains behind and can become trapped between the substrate and the substrate holder contact points or fingers.

The substrate edge residue removal apparatus 104 of embodiments of the present invention provides means to remove the remaining residue. Once the bottom of the substrate has been moved past the waterfall heads 202, 204 and the Marangoni dryer device 208, the substrate edge residue removal apparatus 104 is activated and a gas curtain 210 (e.g., as represented by a dashed line in FIG. 2) is applied to the substrate 108 to blow the residue off of the substrate 108. In some embodiments, only the lower portion (e.g., the lower one third or less) of the substrate 108 is subjected to the gas curtain 210. The substrate holder 106 continues to lift the substrate 108 up past the gas curtain 210 from the substrate edge residue removal apparatus 104. The gas curtain 210 is turned off once the substrate holder 106 is clear of the substrate edge residue removal apparatus 104.

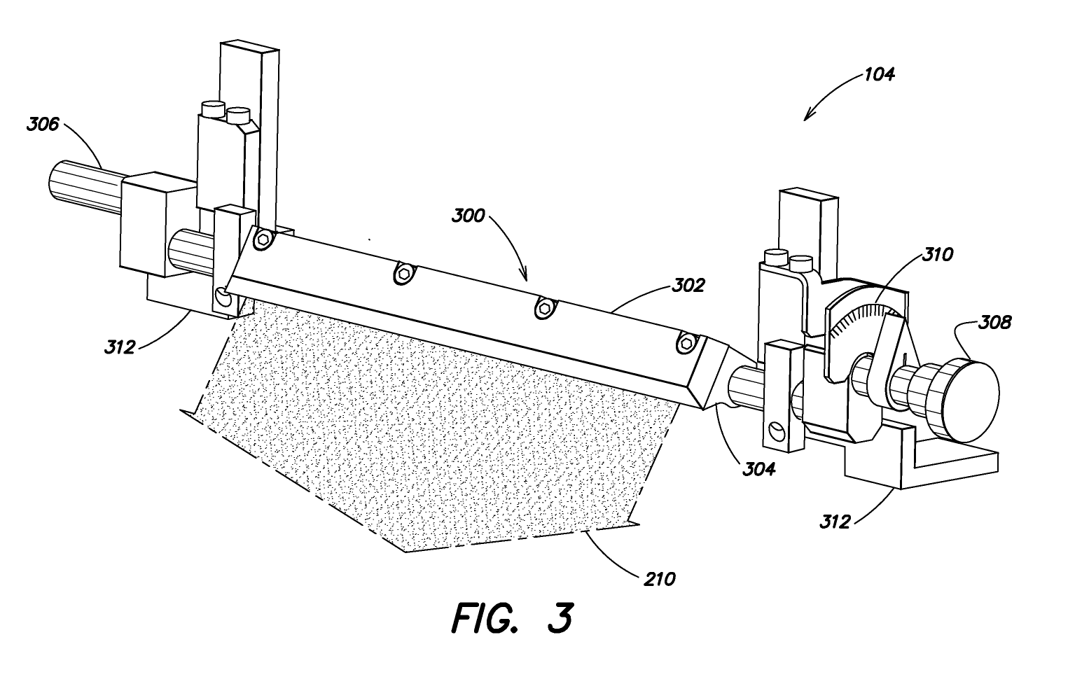

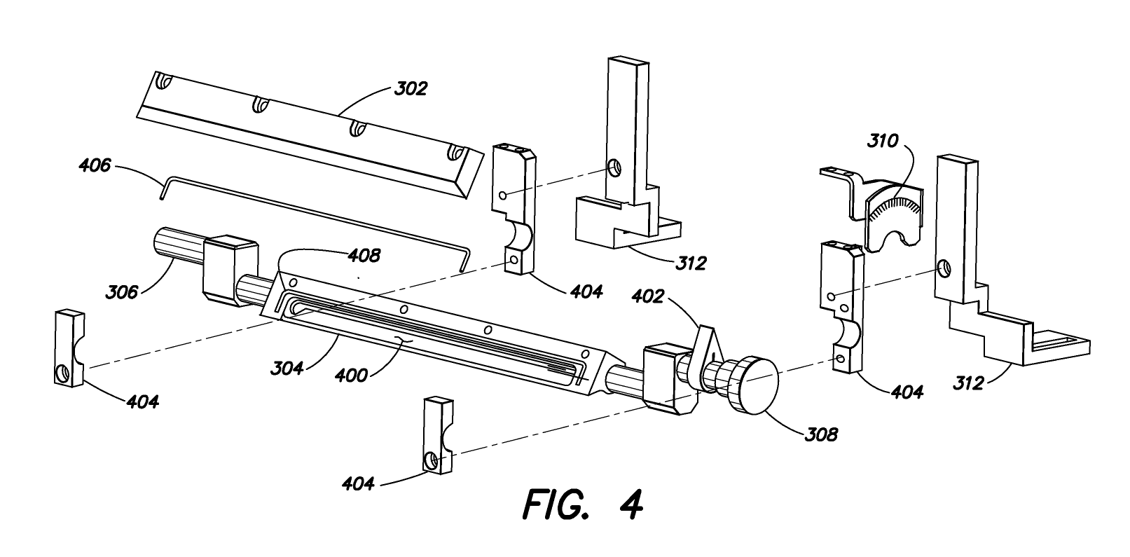

FIG. 3 depicts a magnified perspective view of an example embodiment of a substrate edge residue removal apparatus 104. FIG. 4 shows an exploded perspective view of the substrate edge residue removal apparatus 104 of FIG. 3. The apparatus 104 includes an assembly 300 made from an upper plate 302 removably fastened to a lower body 304 that are spaced to form an output slit out of which the gas curtain 210 can flow. Gas is supplied to the assembly 300 via a gas channel 306 that enters a cavity 400 (FIG. 4) in the lower body 304 from the side of the assembly 300.

An angle adjustment knob 308 is disposed at the end of the apparatus 104 opposite the gas channel 306. The angle adjustment knob 308 includes a pointer 402 that indicates the angle setting of the apparatus 104 on an indexed scale 310. In some embodiments, the angle of the apparatus 104 (i.e., the angle of the gas curtain 210 relative to the major surface of the substrate 108) can be adjusted manually and in others, an actuator under the control of controller 150 can set the angle.

The apparatus 104 is supported and rotatably secured to the frame 102 (FIG. 1) using clamps 404 coupled to brackets 312. In some embodiments, brackets 312 are adjustable so that the height position of the assembly 300 relative to the rest of the system 100 can be adjusted up and down. Further, the brackets 312 can be adjustable laterally to change the horizontal distance between the output slit of the assembly 300 and the substrate 108 (FIGS. 1 & 2). In some embodiments, the height of the apparatus 104 and lateral distance from the substrate 108 can be adjusted manually and in others, an actuator under the control of controller 150 can set the height and lateral position of the apparatus 104. A compressible (e.g., elastic) sealing member 406 is seated in a groove 408 in the lower body 304 of the assembly 300 that surrounds the cavity 400.

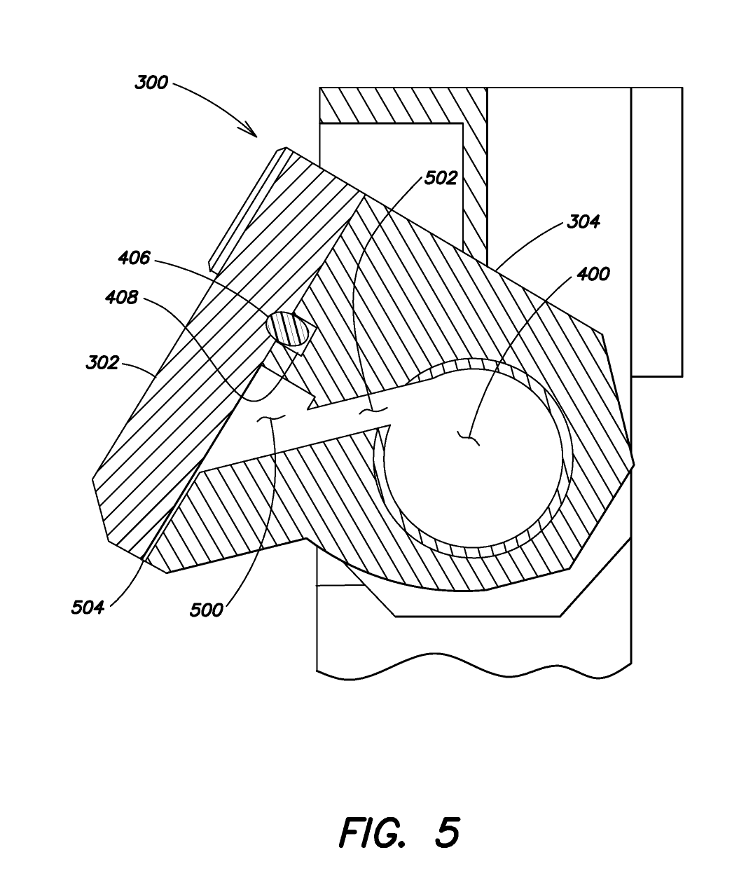

Turning now to FIG. 5, a magnified cross-sectional view of an example embodiment of the assembly 300 is shown. The gas channel 306 (FIG. 3) is in fluid communication with the cavity 400 which is in fluid communication with a plenum 500 via passageway 502. The output slit 504 leads from the plenum 500, between the upper plate 302 and the lower body 304, out toward the substrate 108. A feature of the two piece assembly 300 is that the upper plate 302 can be disassembled from the lower body 304 to facilitate cleaning of the assembly 300 should the assembly 300 become clogged or otherwise need to be cleaned. In addition, the geometry and arrangement of the assembly provides even distribution of the gas along the length of the assembly so that a consistent, continuous and even gas curtain 210 can be output by the assembly 300 with a laminar flow characteristic. Further, in some embodiments, the length of the assembly 300 can be shorter than the diameter of the substrate 108 (e.g., 200 mm, 300 mm, etc.) being cleaned since the gas curtain 210 is only applied to a lower portion of the substrate 108.

The width of the gas curtain 210 is defined by the length of the output slit 504 which can be approximately 5 mm (+/−1 mm) to approximately 300 mm (+/−30 mm). This width is selected to accommodate cleaning the lower portion of 300 mm substrates. Other widths can be used. The thickness of the gas curtain 210 is defined by the height of the output slit 504 which can be approximately 0.025 mm (+/−0.001 mm) to approximately 3 mm (+/−0.5 mm). The output slit can be dimensioned to allow a volume to flow at a rate of approximately 1 slm (+/−0.2 slm) to approximately 100 slm (+/−10 slm) at a pressure in the range of approximately 68947.57 Pa (+/−500 Pa) to approximately 689475.7 Pa (+/−500 Pa). The plenum 500 can have a volume in the range of approximately 0.0626 mm³ (+/−0.005 mm³) to approximately 90000 mm³ (+/−500 mm³). Other practicable dimensions are possible. The various components of the substrate edge residue removal apparatus 104 can be made of any practicable materials such as rigid metals (e.g., stainless steel, aluminum, etc.), ceramic, or various plastics (e.g., PEEK). Other suitable materials may be used.

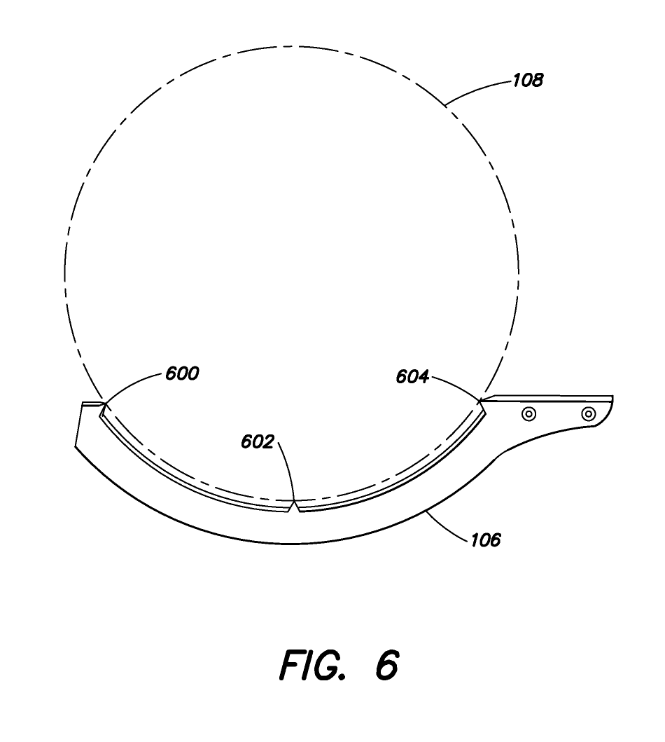

FIG. 6 depicts an example of a substrate holder 106 that can be used with the substrate edge residue removal system 100 of embodiments of the present invention. The example substrate holder 106 is supported and lifted by a robot or an actuator (not shown) that can move the substrate 108 and the substrate holder 106 upward (and downward) past the substrate edge residue removal apparatus 104. The particular example substrate holder 106 depicted in FIG. 6 includes three contact fingers 600, 602, and 604 upon which the substrate 108 sits.

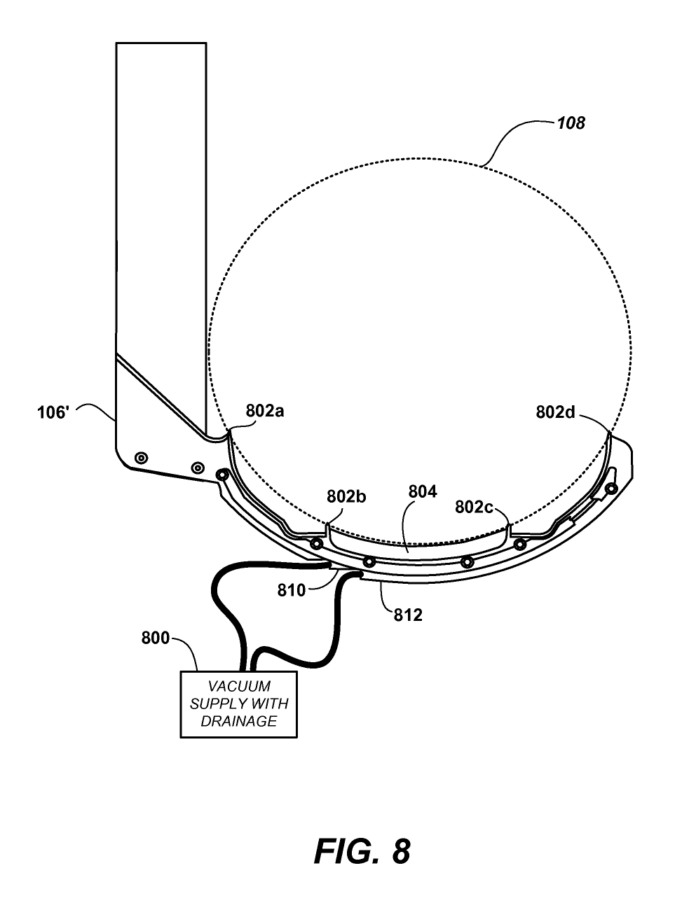

More or fewer contact fingers can be used and can be disposed in different locations than the three shown in FIG. 6. For example, in some embodiments, four contact fingers can be used disposed so that the lowest point of the substrate 108 is not contacted by the substrate holder 106′ as shown in FIG. 8. In such a four contact point configuration, residue that normally moves to the lowest point on the substrate 108 can be more easily and reliably removed without interference from a contact finger.

The substrate holder 106 has utility for holding a substrate 108 in a vertical orientation, lowering the substrate 108 into a bath (e.g., into a rinsing bath), and aiding in the removal of the substrate 108 from the bath in semiconductor device processing. In some embodiments as shown in FIG. 8, the substrate holder 106′ can include a vacuum apparatus 800 adapted to apply vacuum pressure to any residue on the substrate 108 while the substrate is being cleaned with the substrate edge residue removal apparatus 104.

In some embodiments, a substrate holder 106′ may include multiple substrate contact supports 802a-d configured to contact and support a substrate 108. These supports 802a-d may be v-shaped or otherwise-shaped to facilitate draining of fluid from the substrate holder 106′ when the substrate holder 106′ is removed from a fluid bath. In some embodiments, one or more of the substrate contact supports 802a-d may include a vacuum port (not shown) for applying a vacuum at one or more of the supports 802a-d, to further assist in fluid removal. Additionally or alternatively, a slit-shaped vacuum port 804 may be provided between supports 802b and 802c, at the bottom edge of the substrate 108. Vacuum may be applied to the one or more vacuum ports via vacuum inlets 810, 812, for example. The one or more vacuum ports may be operable to apply a vacuum at one or more locations along the bottom edge of a substrate. As such, liquid residue, which formerly could collect at such substrate supports and/or along a bottom edge of a substrate, may be removed. Example substrate holders are described in previously incorporated U.S. application Ser. No. 14/593,841, filed Jan. 9, 2015. Any other suitable substrate holders may be employed.

The various methods described herein may be implemented by, or under the control of, the controller 150, which may be, for example, an appropriately programmed general purpose computer or other computing device. Typically a processor (e.g., one or more microprocessors) will receive instructions from a memory or like device, and execute those instructions via, for example, various actuators, thereby performing one or more methods defined by those instructions. Further, programs that implement such methods may be stored and transmitted using a variety of media (e.g., computer readable media) in any manner. In some embodiments, hard-wired circuitry or custom hardware may be used in place of, or in combination with, software instructions for implementation of the processes of various embodiments. Thus, embodiments of the controller 150 are not limited to any specific combination of hardware and software. The controller 150 may include various components and devices (e.g., a processor, input and output devices, sensors, displays, actuators, and the like) appropriate to perform the method.

A substrate edge residue removal system 100 can be part of a larger post-CMP modular cleaning system. In operation, a substrate 108 can be loaded into the substrate holder 106 and lowered into a cleaning module via a robot, which attaches to and moves the substrate holder 106. The robot may be any suitable robot, such as a gantry robot, a beam robot, or the like. The robot lowers the substrate 108 into a rinsing tank of the cleaning module, and optionally past the waterfall heads 202, 204, which may rinse both sides of the substrate 108. The substrate 108 is fully immersed in the cleaning liquid contained in the rinsing tank for a suitable time, and then is retracted from the tank. The tank may include megasonic or other energized cleaning capabilities in some embodiments.

As the substrate 108 exits the tank, it again passes by the waterfall heads 202, 204 where the substrate 108 may optionally receive a rinse of cleaning liquid. The substrate 108 can be concurrently moved past a Marangoni dryer device 208. The Marangoni dryer device 208 can be an air knife, such as taught in U.S. Pat. Nos. 8,869,422 and 8,322,045, for example. Other configurations of the Marangoni dryer device 208 can be used. After the substrate 108 has been moved past the Marangoni dryer device 208 (e.g., the gas from the Marangoni dryer device 208 is no longer aimed at or contacting the substrate 018), the substrate edge residue removal apparatus 104 can be activated by the controller 150 to deliver a gas curtain 210 starting at the lower third of the substrate 108 while the substrate 108 continues to be lifted. In some embodiments, the substrate can be lifted at a rate of approximately 1 mm/s (+/−0.5 mm/s) to approximately 30 mm/s (+/−1 mm/s). Substantially all of the liquid remaining on the substrate after the Marangoni drying process can be removed by the substrate edge residue removal apparatus 104. In some embodiments, concurrently with the substrate edge residue removal apparatus 104 being activated, vacuum pressure can be applied by the controller 150 to the substrate via the substrate holder 106.

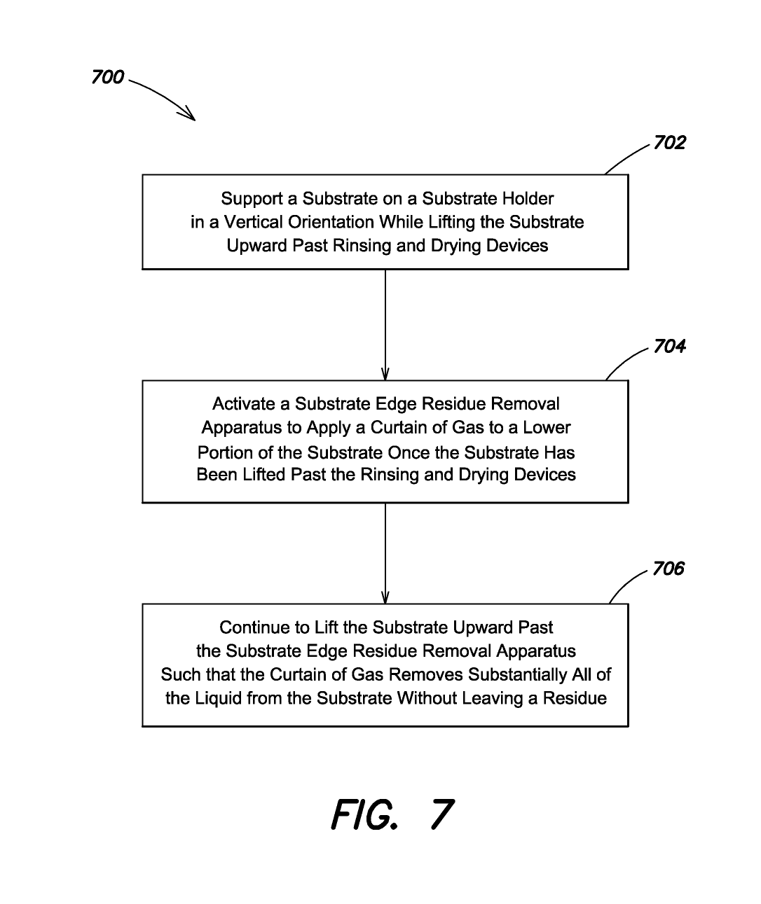

FIG. 7 is a flowchart of a method 700 of cleaning a substrate (e.g., substrate 108). The method 700 may be undertaken following a CMP operation in accordance with embodiments of the present invention. While operation of the substrate edge residue removal system 100 is described primarily with regard to cleaning a substrate 108 after CMP, it will be understood that a similar method may be used elsewhere in the substrate manufacturing process where raising a substrate 108 from a tank of cleaning liquid is performed and where substantially complete removal of residue is desired.

With reference to FIG. 7, the method 700 of cleaning a substrate (e.g., substrate 108) includes, in 702, supporting the substrate on a substrate holder (e.g., substrate holder 106) in a vertical orientation and lifting the substrate upward past rinsing and drying devices (e.g., waterfall heads 202, 204 and a Marangoni dryer device 208). The method can further include activating, in 704, a substrate edge residue removal apparatus (e.g., the substrate edge residue removal apparatus 104) once the substrate has been lifted past the rinsing and drying devices. Activating the substrate edge residue removal apparatus can include opening a gas valve via a controller (e.g., controller 150) to flow an inert gas (e.g., N2 or other gas mixture) into the substrate edge residue removal apparatus to form a curtain of gas (e.g., gas curtain 210) at a lower portion of the substrate. In some embodiments, activating the substrate edge residue removal apparatus can further include aiming an output slit (e.g., output slit 504) of the substrate edge residue removal apparatus at the lower portion of the substrate. In some embodiments, the aiming of the output slit can be performed by the controller. In 704, the method 700 includes continuing to lift the substrate upward past the substrate edge residue removal apparatus such that the curtain of gas removes substantially all of the liquid from the substrate without leaving a residue.

The foregoing description discloses only example embodiments of the invention. Modifications of the above-disclosed assemblies, apparatus, and methods which fall within the scope of the invention will be readily apparent to a person of ordinary skill in the art. While embodiments of the invention have been described primarily with regard to cleaning a substrate after CMP, it will be understood that embodiments of the invention may be employed for other substrate cleaning and/or pre-cleaning applications.

Accordingly, while the invention has been disclosed in connection with example embodiments thereof, it should be understood that other embodiments may fall within the scope of the invention, as defined by the following claims.

The invention claimed is:

1. A substrate edge residue removal apparatus, comprising:
a lower body including a gas cavity; and
an upper plate removably coupled to the lower body,
wherein the lower body and upper plate together form an assembly having a passageway leading from the gas cavity to a plenum and an output slit extending along a length of the plenum and in fluid communication with the plenum.

2. The substrate edge residue removal apparatus of claim 1 wherein, in response to gas being applied to the gas cavity via a gas channel, the assembly is configured to generate an evenly distributed gas curtain along a length of the output slit, the generated gas curtain having laminar flow.

3. The substrate edge residue removal apparatus of claim 1 wherein the assembly is rotatably mountable on a frame to allow the output slit to be angularly adjusted relative to a vertically oriented substrate to be cleaned.

4. The substrate edge residue removal apparatus of claim 1 wherein the assembly includes a sealing member disposed around the gas cavity and adapted to prevent gas from exiting the assembly except via the output slit.

5. The substrate edge residue removal apparatus of claim 1 wherein the assembly is adjustably mountable on a frame to allow a position of the output slit to be vertically and laterally adjusted relative to a vertically oriented substrate to be cleaned.

6. The substrate edge residue removal apparatus of claim 1 wherein the assembly is adapted to be disassembled for cleaning.

7. The substrate edge residue removal apparatus of claim 1 wherein the assembly is adapted to form a gas curtain from a pressurized gas supply of nitrogen and a mixture of nitrogen and isopropyl alcohol vapor.

8. A substrate edge residue removal system, comprising:
an assembly formed from a lower body including a gas cavity and an upper plate removably coupled to the lower body wherein the assembly includes a passageway leading from the gas cavity to a plenum and an output slit extending along a length of the plenum and in fluid communication with the plenum;
a frame supporting the assembly;
a Marangoni drying device coupled to the frame and disposed below the assembly; and
a substrate holder operable to support and to lift a substrate past the output slit of the assembly.

9. The substrate edge residue removal system of claim 8 wherein, in response to gas being applied to the gas cavity via a gas channel, the assembly is configured to generate an evenly distributed gas curtain along a length of the output slit, the generated gas curtain having laminar flow.

10. The substrate edge residue removal system of claim 8 wherein the assembly is rotatably mountable on the frame to allow the output slit to be angularly adjusted relative to a substrate in the substrate holder to be cleaned.

11. The substrate edge residue removal system of claim 8 further comprising a rinsing device disposed below the Marangoni drying device.

12. The substrate edge residue removal system of claim 8 wherein the assembly is adjustably mountable on a frame to allow a position of the output slit to be vertically and laterally adjusted relative to a substrate in the substrate holder to be cleaned.

13. The substrate edge residue removal system of claim 8 wherein the assembly is adapted to be disassembled for cleaning.

14. The substrate edge residue removal system of claim 8 wherein the assembly is adapted to form a gas curtain from a pressurized gas supply of nitrogen and a mixture of nitrogen and isopropyl alcohol vapor.

15. A method of cleaning a substrate, comprising:
supporting a substrate on a substrate holder in a vertical orientation while lifting the substrate upward past a drying device;
activating a substrate edge residue removal apparatus to apply a curtain of gas to a lower portion of the substrate once the substrate has been lifted past the drying device; and
continuing to lift the substrate upward past the substrate edge residue removal apparatus such that the curtain of gas removes substantially all of the liquid from the substrate without leaving a residue.

16. The method of claim 15 wherein activating the substrate edge residue removal apparatus includes opening a gas valve via a controller to flow an inert gas into the substrate edge residue removal apparatus to form a curtain of gas.

17. The method of claim 16 wherein forming a curtain of gas includes forming a gas curtain from a pressurized gas supply of nitrogen and a mixture of nitrogen and isopropyl alcohol vapor.

18. The method of claim 15 wherein activating the substrate edge residue removal apparatus includes aiming an output slit of the substrate edge residue removal apparatus at the lower portion of the substrate.

19. The method of claim 15 wherein activating the substrate edge residue removal apparatus includes applying vacuum pressure to liquid on the substrate via vacuum slots in the substrate holder concurrently with applying the curtain of gas.

20. The method of claim 15 further comprising deactivating the substrate edge residue removal apparatus once the substrate has been lifted past the substrate edge residue removal apparatus.
